(19) United States
(12) Patent Application Publication
(10) Pub. No.: US 2004/0089790 A1
(43) Pub. Date: May 13, 2004

(54) Spatially modulated photodetectors

(76) Inventors: Mark E. Rubin, San Jose, CA (US); Yang Zhao, Fremont, CA (US)

Correspondence Address: FLIESLER MEYER, LLP, FOUR EMBARCADERO CENTER, SUITE 400, SAN FRANCISCO, CA, 94111, US

(21) Appl. No.: 10/370,950

(22) Filed: Feb. 21, 2003

Related U.S. Application Data
(60) Provisional application No. 60/424,749, filed on Nov. 7, 2002.

(51) Int. Cl. H01L 31/00

(52) U.S. Cl. 250/214.1

(57) ABSTRACT

A photodetector includes a first conductivity type semiconductor material (e.g., a p-type material) and one or more regions of semiconductor material of a second conductivity type (e.g., regions of n-type material), each forming a pn junction with the first conductivity type semiconductor material. The one or more regions collectively have a first layout area. One or more further regions of semiconductor material of the second conductivity type (e.g., further regions of n-type material) each form a pn junction with the first conductivity type semiconductor material. The one or more further regions collectively having a second layout area. A light blocking material covers the one or more further regions. The first layout area is greater than the second layout area.

### PRIORITY CLAIM

This application claims priority to U.S. patent application Ser. No. 60/424,749, entitled “Improved Spatially Modulated Photodetectors,” filed Nov. 7, 2002.

### FIELD OF THE INVENTION

The present invention relates generally to photodetectors. Specific embodiments are directed to improved CMOS photodetectors having fast responses.

### BACKGROUND

For various reasons, there has recently been an increased interest in the production of a fast photodetector produced using complementary-metal-oxide semiconductor (CMOS) technology. First, CMOS circuitry is generally less expensive than other technologies, such as Gallium Arsenide or bipolar silicon technologies. Further, CMOS circuitry generally dissipates less power than other technologies. Additionally, CMOS photodetectors can be formed on the same substrate as other low power CMOS devices, such as metal-oxide semiconductor field effect transistors (MOSFETs).

However, despite the potential advantages, there are various reasons why conventional CMOS technology has not been optimal for producing a fast photodetector. More specifically, photodetectors produced using CMOS technology have proven to be much slower than photodetectors produced using other technologies, such as bipolar silicon technology. The slower the photodetector, the lower the bandwidth of information that can be detected using the photodetector. The graphs of FIGS. 2A and 2B, discussed below, are used to explain this in more detail.

FIG. 1 shows a cross section of a conventional CMOS photodetector 102, which includes an n⁺ region 104, which is heavily doped, and a p⁻ region 106, which is lightly doped. The n⁺ region 104 and p⁻ region 106 form a pn junction, and more specifically, a n+/ p junction. This n⁺/p⁻ junction is reversed biased, e.g., using a voltage source 110. The reverse bias causes formation of a depletion region 108, where there is no mobile charge (i.e., no charge carriers) and a high electric field.

When light 112 is incident on photodetector 102 (and more specifically on n⁺ region 104), electron-hole pairs are produced. Electrons are immediately pulled toward n+region 104, while holes get pushed down toward p⁻ region 106. These electrons are captured in n⁺ region 104 and produce a current, which, for example, can be detected using a current detector 114. As long as the above described process occurs in the high electric field region (i.e., in depletion region 108), this process happens very quickly. However, light is absorbed with a characteristic depth determined by the wavelength of light. For certain wavelengths (e.g., 780 nm used in CD technology, or 640 nm used in DVD technology) the depth at which a significant portion of the absorption occurs in deeper than depletion region 108. Thus, many carriers are generated below depletion region 108, where there is no electric field. When carriers are generated where there is no electric field, the carriers wander around for a while before eventually entering the electric field and then getting captured. In other words, the carriers that are generated outside the depletion region are much slower than the carriers generated within the depletion region. This makes for a slow detector. The slow response of conventional CMOS photodetector 102 will now be explained with reference to FIGS. 2A and 2B.

FIG. 2A is an exemplary graph of light intensity versus time, for light 112 incident on conventional CMOS photodetector 102. FIG. 2B is an exemplary graph of the current (generated by convention CMOS photodetector 102 in response to the incident light) versus time. The same time scale is used in FIGS. 2A and 2B. As can be seen in the FIGS., the photodetector generates substantially no current when there is no light incident on the photodetector. When light is detected, the current increases until it reaches a maximum current. The current then reduces to substantially no current when the light is no longer incident on the photodetector. Optimally, the current response tracks the light exactly. However, as can be seen from FIGS. 2A and 2B, the current has a substantial rise time (tᵣ) and fall time (t_{f}). The rise time is approximately 50 nsec (i.e., tᵣ˜50 nsec).

It is desirable to reduce the rise time to less than 10 nsec, and preferably to about 1 nsec, to thereby make a very fast photodetector. This can be theoretically accomplished by maximizing the number of fast carriers and minimizing the number of slow carriers. However, slow carriers are fundamentally present when using generic CMOS technology. Thus, the slow carriers must be dealt with.

Two recent articles discuss what is referred to as a “spatially modulated” CMOS photodetector, which is explained with reference to FIGS. 3A and 3B. These articles, entitled “Modulated Light Detector in CMOS with Amplifier Receiver Operating at 180 Mb/s for Optical Data Link Applications and Parallel Optical Interconnects Between Chips,” by M. Kuijk et al., IEEE Journal of Selected Topics in Quantum Electronics, Vol. 4, No. 6, November/December 1998 (pages 1040-1045), and “Asynchronous 250-Mb/s Optical Receivers with Integrated Detector in Standard CMOS Technology for Optocoupler Applications,” by C. Rooman et al., IEEE Journal of Solid-State Circuits, Vol. 35, No. 7, July 2000 (pages 953-957), are each incorporated herein by reference.

Shown in FIGS. 3A and 3B, respectively, are top and cross-sectional views of a spatially modulated CMOS photodetector 302, as suggested in the above mentioned articles. As shown, photodetector 302 includes a plurality of identical rectangular shaped n⁺ regions 304 that are implanted in a p⁻ region 306. Half of the n⁺ regions 304 (i.e., regions 304b) are covered by a light blocking material 316, while the other half of the n⁺ regions 304 (i.e., regions 304a) are not covered. The covered n⁺ regions 304b are all electrically connected together, as shown in FIG. 3A. Similarly, the uncovered n⁺ regions 304a are all electrically connected together. Six separate pn junctions are formed, each of which is identically reversed biased (as was photodetector 102, discussed above), thereby forming six separate depletion regions 308.

When light 312 is incident on photodetector 302, carriers are not generated in the depletion regions corresponding to covered n⁺ region 304b (i.e., in depletion regions 308b) or below these depletion regions, because no light is incident on covered n⁺ region 304b. The light 112 incident on uncovered n⁺ regions 304a generates carriers in the corresponding depletion regions 308a and outside (e.g., below) these depletion regions where there is no electric field. The carriers generated in depletion regions 308a are quickly captured in uncovered n⁺ regions 304a (which are all electrically connected together). However, the slow carriers generated below depletion regions 308a wander around for awhile before eventually entering an electric field and then getting captured. After wandering around (e.g., in a left or right direction), some of the slow carriers will eventually be captured by one of covered n⁺ regions 304b. In fact, about half of the slow carriers are eventually captured by covered n⁺ regions 304b and the other half are captured by uncovered n⁺ regions 304a. This half and half capture is due to the substantially random behavior of the slow carriers, the identical shape of each n⁺ region 304, the fact that a layout area associated with uncovered n⁺ regions 304a is equal to a layout area associated with covered n⁺ regions 304b, and the identical biasing of each pn junction.

The carriers that are captured by the uncovered n⁺ regions 304a produce a current, referred to as the immediate current (i_{I}), because a majority of the current is created immediately by the quickly captured carriers (also referred to as fast carriers). A small portion of the immediate current is due to later captured slow carriers. The carriers captured by covered n⁺ regions 304b produce a current, referred to as the deferred current (i_{D}), because the current is produced by later (i.e., deferred) captured slow carriers.

FIG. 4A is an exemplary graph showing light intensity versus time for light 312 incident on spatially modulated photodetector 302. FIG.4B is an exemplary graph showing the response associated with the uncovered n⁺ regions 304a. FIG.4C is an exemplary graph showing the response associated with the covered n⁺ regions 304b. As shown in FIG. 4D, subtracting the response of FIG. 4C from the response shown in FIG. 4B results in a very quick photodetector, with fast rise and fall times.

While spatially modulated photodetector 302 is an improvement over conventional CMOS photodetector 102 previously described, photodetector 302 still has some disadvantages. First, a large portion (i.e., about half) of spatially modulated photodetector 302 is covered (i.e., blocked). In other words, about half of photodetector 302 does not collect light. This reduces the sensitivity and detectivity of photodetector 302. Further, where area efficiency is defined as the area collecting light (i.e., the uncovered area) divided by the total available area for collecting light, the area efficiency of spatially modulated photodetector 302 is only about 50%.

### SUMMARY

It would be beneficial to produce faster CMOS photodetectors that have improved sensitivity, detectivity and/or area efficiency as compared to the photodetectors suggested in the above mentioned articles.

Embodiments of the present invention are directed to photodetectors that have a fast response times, and the circuitry and/or other devices that are used to adjust the currents and/or voltages generated by photodetectors. In other words, embodiments of the present invention are directed to systems or apparatuses that include photodetectors and systems or apparatuses that are used with photodetectors. While features of the present invention will produce the most significant improvements in CMOS photodetectors, the features of the present invention can be implemented in other technologies, such as (but not limited to) bipolar silicon technology and Gallium Arsenide technology.

A photodetector, according to an embodiment of the present invention, includes a first conductivity type semiconductor material (e.g., a p-type material) and one or more regions of semiconductor material of a second conductivity type (e.g., regions of n-type material), each forming a pn junction with the first conductivity type semiconductor material. The one or more regions collectively have a first layout area. One or more further regions of semiconductor material of the second conductivity type (e.g., further regions of n-type material) also each form a pn junction with the first conductivity type semiconductor material. The one or more further regions collectively having a second layout area. A light blocking material covers the one or more further regions. The first layout area is greater than the second layout area, thereby producing a spatially modulated photodetector with increased area efficiency.

In accordance with an embodiment of the present invention, a photodetector includes a p-type region and a first n-type region forming a first pn junction with the p-type region. The first n-type region has a first layout area. A second n-type region, separated from the first n-type region, forms a second pn junction with the p-type region. The second n-type region has a second layout area that is greater than the first layout area. A light blocking material covers the first n-type region.

Prior to exposing the photodetector to light, each of the first and second pn junctions are reverse biased. When light is incident on the photodetector, carriers are produced in the p-type region. A portion of the carriers are quickly captured by the second n-type region. A remaining portion of the carriers are slow carriers that wander around in the p-type region prior to being captured. A first portion of the slow carriers eventually are captured by the first n-type region. A second portion of the slow carriers are eventually captured by the second n-type region. The first pn junction generates a first current resulting from the first portion of the slow carriers, and the second pn junction generates a second current resulting from both the quickly captured portion of the carriers (i.e., the fast carriers) and the second portion of the slow carriers. In accordance with an embodiment of the present invention, a current adjuster adjusts at least one of the first and second currents so that the first current is substantially equal to a portion of the second current that is due to the second portion of the slow carriers. Then the first current is subtracted from the second current (after one or both of the first and second currents are adjusted by the current adjuster), resulting in a difference current having a fast response.

In accordance with embodiments of the present invention, rather than determining a difference between currents, current-to-voltage converters are used to convert the currents to voltages. Then one of the voltages is subtracted from the other to produce a difference voltage signal having a fast response.

Further embodiments of the present invention are directed to photodetectors that include a plurality of covered regions and uncovered regions of a first conductivity type that are implanted in a material of a second conductivity type. In accordance with embodiments of the present invention, the collective layout area of the uncovered regions is greater than the collective layout area of the covered regions. Embodiments of the present invention are also directed to specific geometrical layouts of the regions. For example, photodetectors in accordance with specific embodiments of the present invention have layout areas that are generally symmetrical in both the X and Y directions.

Further embodiments, and the features, aspects, and advantages of the present invention will become more apparent from the detailed description set forth below, the drawings and the claims.

### BRIEF DESCRIPTION OF THE DRAWINGS

FIG. 1 is a cross-section of a conventional CMOS photodetector;

FIG. 2A is a graph showing light intensity versus time for light incident on the conventional CMOS photodetector of FIG. 1;

FIG. 2B is a graph showing current versus time for a current produced by the conventional CMOS photodetector of FIG. 1, in response to the light represented in FIG. 2A;

FIG. 3A is a top view of a spatially modulated CMOS photodetector;

FIG. 3B is a cross-section of the CMOS photodetector shown in FIG. 3A;

FIG. 4A is a graph showing light intensity versus time for light incident on the spatially modulated CMOS photodetector of FIGS. 3A and 3B;

FIG. 4B is a graph showing current versus time for a current produced by the uncovered portion of the spatially modulated CMOS photodetector of FIGS. 3A and 3B, in response to the light represented in FIG. 4A;

FIG. 4C is a graph showing current versus time for a current produced by the covered portion of the spatially modulated CMOS photodetector of FIGS. 3A and 3B, in response to the light represented in FIG. 4A;

FIG. 4D is a graph showing current versus time when the response of FIG. 4C is subtracted from the response of FIG. 4B;

FIG. 5A is a top view of a CMOS photodetector, according to an embodiment of the present invention;

FIG. 5B is a cross-section of the CMOS photodetector of FIG. 5A;

FIG. 6A is a high level diagram illustrating features of embodiments of the present invention;

FIG. 6B is a high level circuit diagram illustrating features of an embodiment of the present invention;

FIG. 7A is a top view of a CMOS photodetector, according to an embodiment of the present invention;

FIG. 7B is a cross-section of the CMOS photodetector of FIG. 7A;

FIG. 8A is a top view of a CMOS photodetector, according to an embodiment of the present invention;

FIGS. 8B and 8C are cross-sections of the CMOS photodetector of FIG. 8A;

FIG. 9A is a top view of a CMOS photodetector, according to an embodiment of the present invention; and

FIGS. 9B and 9C are cross-sections of the CMOS photodetector of FIG. 9A.

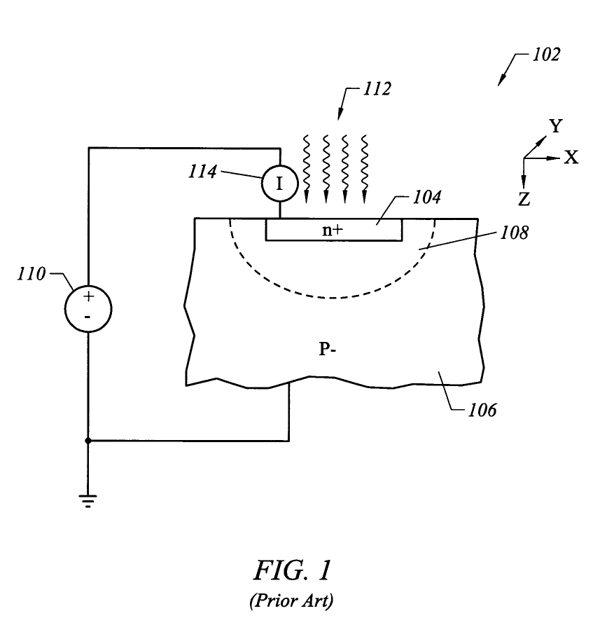

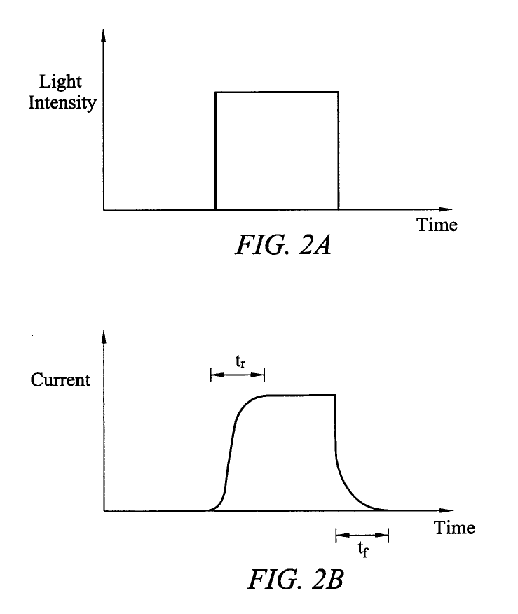

### DETAILED DESCRIPTION

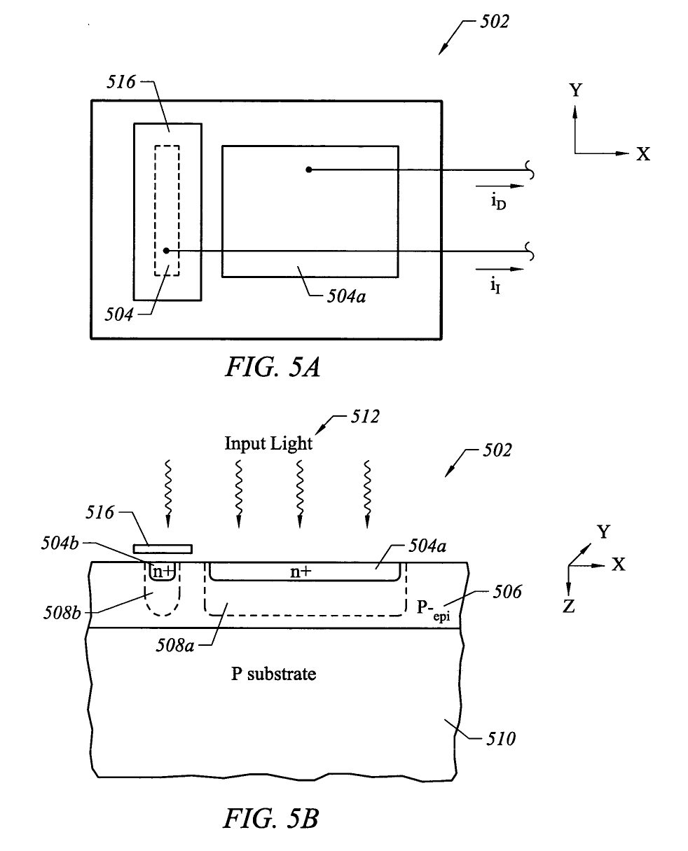

Shown in FIGS. 5A and 5B, respectively, are top and cross-sectional views of a CMOS photodetector 502, according to an embodiment of the present invention. Photodetector 502 is formed on or within a substrate (e.g., a silicon wafer). As shown, photodetector 502 includes an n⁺ region 504a and an n⁺ region 504b that are implanted in a p₋ epi region 506, which is grown on a p substrate 510. Two separate pn junctions are formed, each of which is reversed biased, thereby forming depletion regions 508a and 508b. A light blocking material 516 covers n⁺ region 504b, while n⁺ region 504a is not covered. Light blocking material 516 is likely a metal or polysilicon mask, but can be made of other materials that will block the wavelength of the light incident on the photodetector. Preferably, the p⁻ epi region 506 is very lightly doped. Placing the n⁺ regions 504 in a⁻ epi region 506 provides improved quantum efficiency as compared to placing the n⁺ regions 504 directly in the p substrate 510 (as in the previously described photodetector 302). However, although though not preferred, many embodiments of the present invention will also work where the n⁺ regions 504 are placed directly in a p substrate.

The layout of a chip is a map of the surface of the chip. When producing a CMOS device, the depth of each n⁺ region (i.e., the thickness in the Z direction shown in the FIGS.) is generally fixed by the process. However, the layout area, which is the area of a region (i.e., in the X-Y plane shown in the FIGS.) can be varied. As can be appreciated from FIG. 5A and 5B, in this embodiment of the present invention, uncovered n⁺ region 504a has a greater layout area than covered n⁺ region 504b. This causes photodetector 502 to have improved sensitivity and area efficiency, as compared to the previously described photodetector 302. It is noted that uncovered n⁺ region 504a and covered n⁺ region 504b can be referred to as different portions of the same photodetector (i.e., uncovered and covered portions of photodetector 502), or as portions of separate photodetectors (i.e., as a portion of an uncovered photodetector 502a and a portion of a covered photodetector 502b). In other words, photodetector 502 can be thought of as including two distinct photodetectors, uncovered photodetector 502a and covered photodetector 502b.

When light 512 is incident on photodetector 502, carriers are not generated in depletion region 508b corresponding to covered n⁺ region 504b or be low depletion region 508b, because no light is incident on covered n⁺ region 504b. The light 512 incident on uncovered n⁺ region 504a generates carriers in the corresponding depletion region 508a and below depletion region 508a where there is no electric field. The carriers generated in depletion region 508a are quickly captured in uncovered n⁺ region 504a. The quickly captured carriers are often referred to as fast carriers. The slow carriers generated below depletion region 508a wander around for a while (e.g., for up to about 50 nsec) before eventually entering an electric field and then getting captured. After wandering around (e.g., in the X or Y direction), the slow carriers will eventually be captured by covered n⁺ regions 504b or uncovered n⁺ region 504a. However, because uncovered n⁺ region 504a and its corresponding depletion region 508a are larger than covered n⁺ region 504b and its corresponding depletion region 508b, uncovered n⁺ region 504a will capture more of the slow carriers than covered n⁺ region 504b. The slow carriers captured by covered n⁺ region 504b produce a deferred current (i_{D}). The carriers capture by uncovered n⁺ region 504a (including fast carriers and slow carriers) produce an immediate current (i_{I}).

For at least the reason that n⁺ region 504a is uncovered, and n⁺ region 504b is covered, more total carriers are captured by uncovered n⁺ region 504a than covered n⁺ region 504b, causing the immediate current (i_{I}) to be greater than the deferred current (i_{D}). Further, because uncovered n⁺ region 504a and its corresponding depletion region 508a are larger than covered n⁺ region 504b and its corresponding depletion region 508b, uncovered n⁺ region 504a will capture more of the slow carriers than covered n⁺ region 504b, causing the immediate current (i_{I}) to be even greater than the deferred current (i_{D}), as compared to if the covered and uncovered n⁺ regions were of the same size.

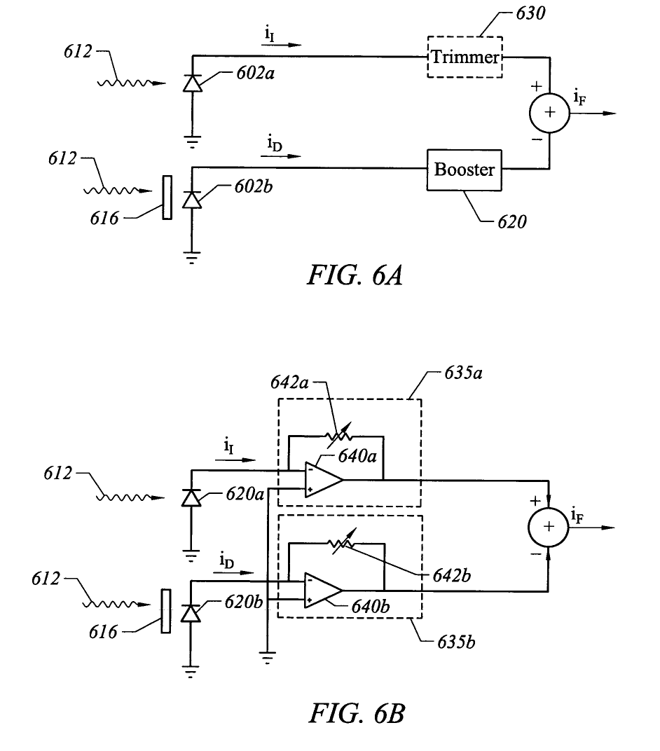

To produce a fast photodetector, the deferred current (i_{D}) should be subtracted from the immediate current (i_{I}) to attempt to produce a quick response. In order for this subtraction process to produce the desired results, the portion of immediate current (i_{I}) produced by the captured slow carriers should be substantially equal to the deferred current (i_{D}). However, it is not that simple in the present case, because these are not substantially equal, as just explained above. Embodiments of the present invention overcome this. Such embodiments will now be explained with reference to FIG. 6A.

FIG. 6A shows a high level diagram of an embodiment of the present invention, which includes a uncovered portion 602a of a photodetector (also simply referred to as an uncovered photodetector 602a) and a covered portion 602b of a photodetector (also simply referred to as covered photodetector 602b). Covered photodetector 602b is shown as being covered or blocked by a light blocking material 616, which blocks incident light 612. Uncovered photodetector 602a is intended to represent the pn junction formed by uncovered n⁺ region 504a and p⁻ region 506, shown in FIGS.5A and 5B. Similarly, covered photodetector 602b is intended to represent the pn junction formed by covered n⁺ region 504b and p region 506. As explained above in the description of FIGS. 5A and 5B (and pictorially shown in FIG. 6A), uncovered n⁺ region 504a is larger than covered n⁺ region 504b, causing the portion of the immediate current (i_{I}) due to slow carriers to be greater than the entire deferred current (i_{D}). Remember, the deferred current is due primarily, if not completely, to slow carriers.

As also explained above, to produce a fast detector using the above described subtraction method, the portion of immediate current (i_{I}) due to slow carriers should be substantially equal to the entire deferred current (i_{D}). This leaves only the quickly captures carriers (i.e., fast carriers) when the deferred current (i_{D}) is subtracted from the total immediate current (i_{I}), resulting in a quick response. However, because the uncovered n⁺ region 504a is larger than covered n⁺ region 504b, the portion of immediate current (i_{I}) due to slow carriers is greater than the entire deferred current (i_{D}), as just mentioned. Thus, simply subtracting the total immediate current (i_{I}) from the deferred current (i_{D}) (where uncovered n⁺ region 504a is larger than covered n⁺ region 504b) will not give as quick a response as desired.

Accordingly, embodiments of the present adjust the deferred current (i_{D}) and/or immediate current (i_{I}) prior to one being subtracted from the other. More specifically, in accordance with a preferred embodiment of the present invention, a current booster 620 is used to boost (i.e., increase) the deferred current (i_{D}) so that it is substantially equal to the portion of the immediate current (i_{I}) due to slow carriers, prior to the deferred current (i_{D}) being subtracted from the immediate current (i_{I}). The result is a detector current (i_{F}) having a fast response. Preferably, i_{F} is maximized to produce as sensitive a detector as possible (i.e., to maximize the sensitivity of the detector). This can be accomplished by maximizing the immediate current (i_{I}) and minimizing the deferred current (i_{D}), since i_{F}=i_{I}−boosted i_{D}.

In accordance with another embodiment of the present invention, a current trimmer 630 is used to trim (i.e., decrease) the immediate current (i_{I}) so that the portion of the immediate current (i_{I}) due to slow carriers is substantially equal to the deferred current (i_{D}), prior to the deferred current (i_{D}) being subtracted from the immediate current (i_{I}). This embodiment is not as optimal as the previous described embodiment (using booster 630), because it does not take advantage of the higher current associated with the uncovered n⁺ region 504a. Thus, the photodetector produced using current trimmer 630 would not be as sensitive as the photodetector produced using current booster 620. That is why the use of a current booster 620 to boost the deferred current is preferred. More specifically, it is advantageous to not trim the immediate current in order to maximize the sensitivity of the photodetector.

In still another embodiment, both current booster 620 and current trimmer 630 are used.

In each of the above embodiments, it is likely that the immediate current (i_{I}) and the deferred current (i_{D}) are each amplified by respective amplifiers (not specifically shown in FIG. 6A) prior to being provided to current trimmer 630 or current booster 620.

Alternatively, or additionally, amplifiers are implemented in current trimmer 630 and/or current booster 620. Alternatively, currents can be converted to voltages, and the voltages can be appropriately adjusted in a similar manner. An exemplary current-to-voltage circuit is discussed below, but is not meant to limit the invention to the exemplary circuit.

FIG. 6B is a somewhat lower level diagram used to describe an embodiment of the present invention. In this embodiment, the immediate current (i_{I}) is provided to an amplifier circuit 635a, which includes an operational amplifier 640a and a resistor 642a. Similarly, deferred current (i_{D}) is provided to a similar amplifier circuit 635b, which includes an operational amplifier 640b and a resistor 642b. As arranged, amplifier circuits 635a and 635b convert the respective input currents to voltages. The voltage associated with the deferred current (i_{D}) is then subtracted from the voltage associated with the immediate current (i_{I}). As discussed above, the uncovered n⁺ region 504a (of photodetector 602a) is larger than covered n⁺ region 504b (of photodetector 602b). This should be compensated for prior to the subtraction.

In accordance with an embodiment of the present invention, resistors 642a and/or 642b, which may be variable resistors, are used to adjust the gains of the amplifiers appropriately such that a voltage associated with the portion of the immediate current (i_{I}) due to slow carriers is substantially equal a voltage associated with the deferred current (i_{D}). As with each of the embodiments of the present invention, the appropriate values for components (e.g., for resistors 642a and/or 642b) can be determined in any of a number of different manners. For example, simulations can be used to determine the appropriate values of resistors 642a and/or 642b. In another embodiment, trial and error type experimentation can be used to determine the appropriate values of resistors 642a and/or 642b. In still another embodiment, theoretical calculations can be performed. More likely, combinations of these various methods can be used to appropriately select the proper gains of amplifiers 625a and 635b. For example, simulations and/or theoretical calculations can be used to determine approximate values for resistors 642a and/or 642b. Then trial and error type experimentation can be used to fine tune the values.

The circuit shown in FIG. 6B is an exemplary implementation of the present invention that is not meant to be limiting. One of ordinary skill in the art will appreciate that many other ways for adjusting currents and/or voltages are within the spirit and scope of the present invention. For example, programable devices (e.g., a programable digital-to-analog converter (DAC)) can be used to appropriately adjust voltages and/or currents. An advantage of using a programable device is that it may selectively adjust the appropriate gain(s) based on additional variables, such as temperature.

It is also noted that current signals or voltage signals can be converted into the digital domain and all further processing of these signals (e.g., adjusting of one or more signals and determining a difference between signals) can be performed in the digital domain, rather than using analog components. Such digital domain processing can be performed using dedicated digital hardware or on a general purpose processor, such as a microprocessor.

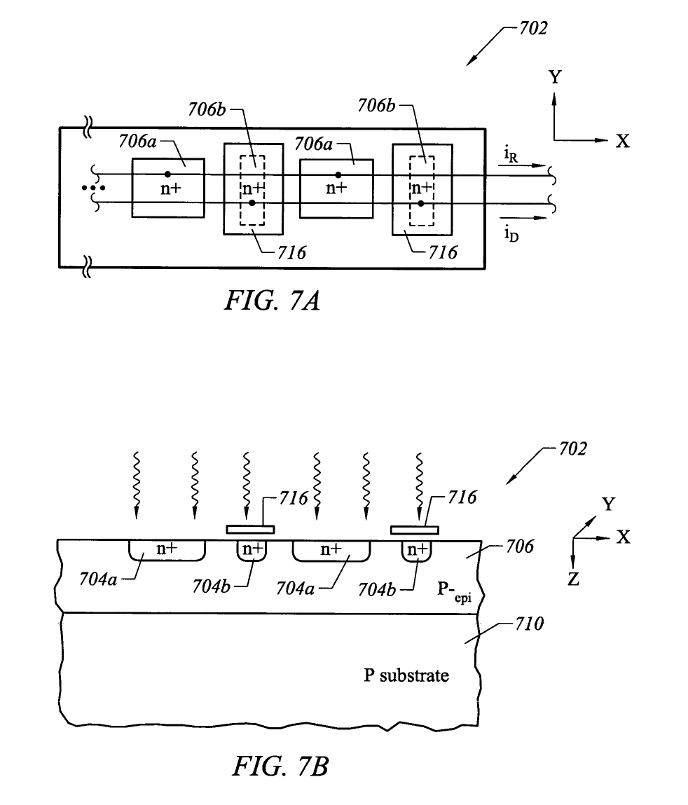

Shown in FIGS. 7A and 7B, respectively, are top and cross-sectional views of a CMOS photodetector 702, according to an embodiment of the present invention. Photodetector 702 is similar to photodetector 502 in that each uncovered n⁺ region 702a is larger than each covered n⁺ region 702b (covered by light blocking material 716). However, in photodetector 702 there are multiple uncovered n⁺ regions 704a and multiple covered n⁺ regions 704b. As can be seen in FIG. 7A, uncovered n⁺ regions 704a are electrically connected together and multiple covered n⁺ region 704b are electrically connected together. The n⁺ regions 704a and 704b are shown as being implanted in a p⁻ epi region 706, which is grown on a p substrate 710. For ease of illustration, the depletion regions (produced by reverse biasing the pn junctions) are not shown in FIG. 7B or any of the remaining FIGS.

Remember that slow carriers are generated below the uncovered n⁺ region, but not below the covered n⁺ region. The closer an uncovered n⁺ region is to a slow carrier, the better chance that the uncovered n⁺ region may collect that slow carrier. Where there is a single uncovered n⁺ region and a single covered n⁺ region, most of the slow carriers will get collected by the uncovered n⁺ region, requiring significant boosting of the deferred current (i_{D}) prior to its subtraction from the immediate current (i_{I}). The more the deferred current (i_{D}) is boosted (prior to the subtraction), the less sensitive the photodetector. An advantage of an embodiment including multiple uncovered and covered n⁺ regions is that a greater percentage of the slow carriers will get collected by the covered n⁺ regions 702b, as compared to an embodiment including a single uncovered n⁺ region and a single uncovered n⁺ region. Thus, the deferred current (i_{D}) will require less boosting prior to its subtraction from the immediate current (i_{I}), resulting in a more sensitive detector.

The inventors of the embodiments of the present invention have realized that in addition to making the uncovered n⁺ region(s) larger than the covered n⁺ region(s), there are certain photodetector layout geometries that are better than others. More specifically, certain geometries have better area efficiency than others, improving sensitivity and detectivity. Additionally, certain geometries produce greater immediate currents (i_{I}), and deferred currents (i_{D}) that require less boosting than others, improving sensitivity and detectivity. Preferably, a geometry results in good area efficiency, thereby increasing the immediate current (i_{I}), while also producing a deferred current (i_{D}) that requires less boosting, resulting in a photodetector having excellent sensitivity and detectivity.

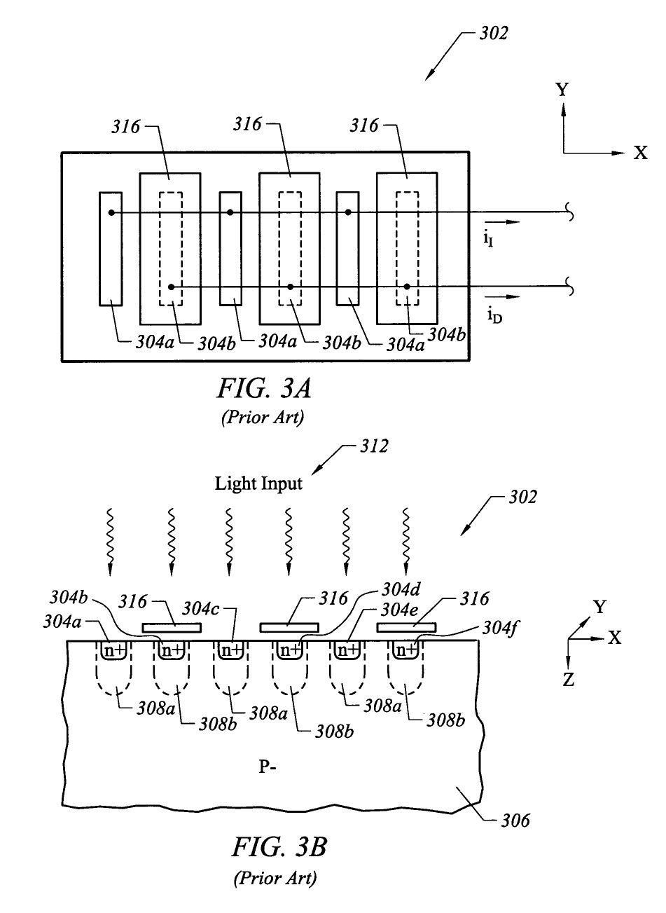

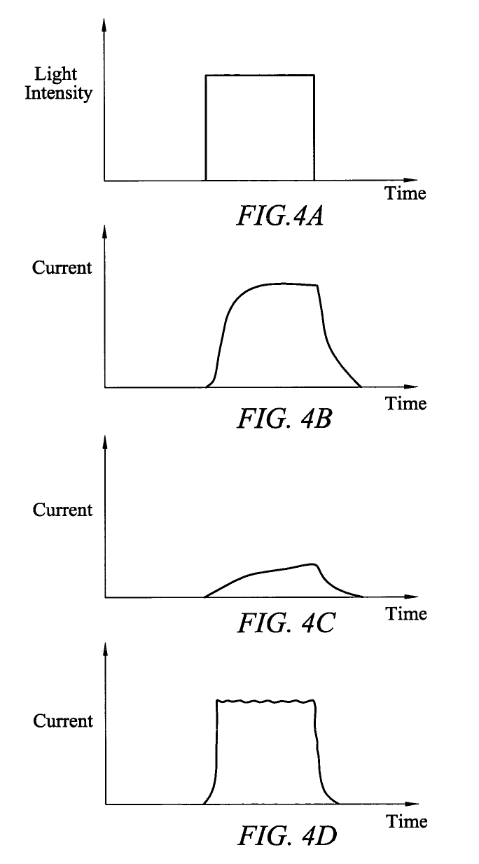

The layout geometry shown in FIGS. 7A and 7B is symmetrical in one direction (i.e., the X direction shown), but not in the other direction (i.e., the Y direction shown). This geometry has better area efficiency than photodetector 302 of FIGS. 3A and 3B (because the collective layout area of the uncovered n⁺ regions 702a is greater than the collective layout area of the covered n⁺ regions 702b). However, the inventors of the present invention have determined that better even sensitivity and detectivity can be achieved if the layout geometry is symmetrical in both the X and Y directions.

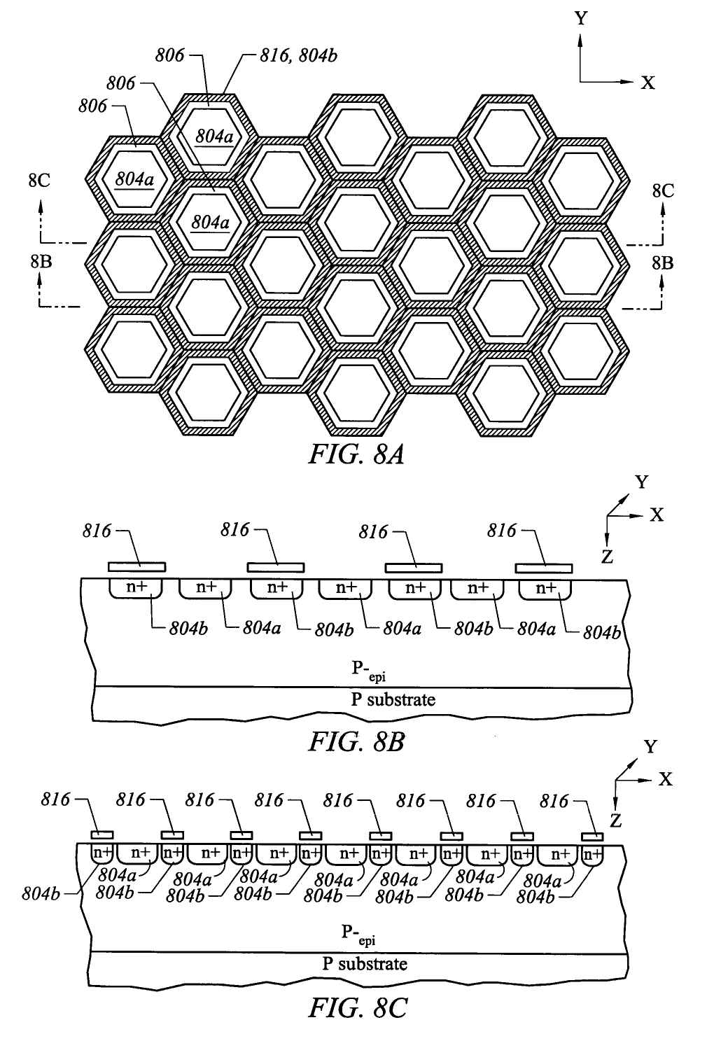

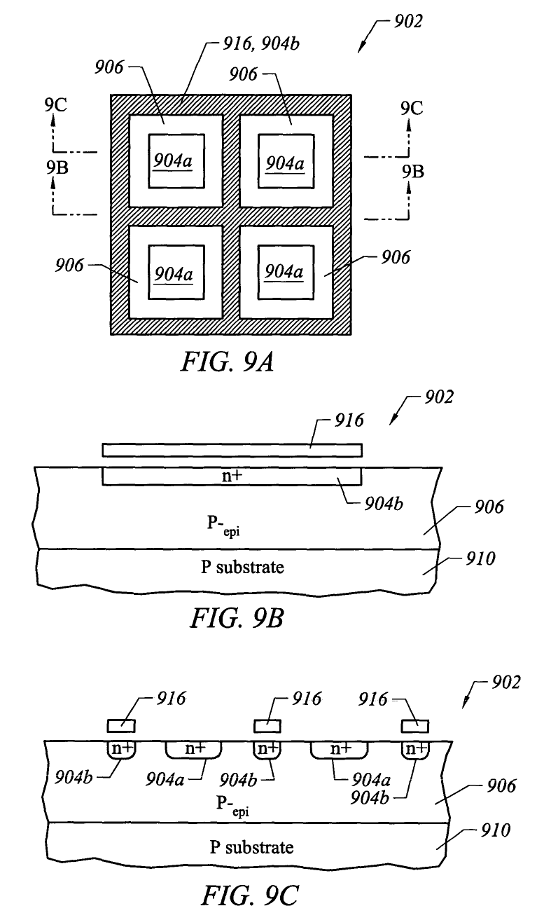

Photodetector 902, shown in FIGS. 9A-9C, is an embodiment of the present invention where the layout geometry is symmetric in both the X and Y directions (however, the collective layout area of the uncovered n⁺ regions 902a may not be greater than the collective layout area of the covered n⁺ regions 902b). FIG. 9A illustrates a top view of a photodetector 902, and FIGS. 8B and 8C are cross-sectional views of photodetector 902. In these FIGS., uncovered n⁺ regions 904a are generally square shaped regions that are electrically connected to one another (electrical connections are not shown), and covered n⁺ region 904b (covered by light blocking material 916) is shown as being shaded and surrounding square shaped uncovered n⁺ regions 904a. As in all CMOS devices, there needs to be at least a minimum separation between separate n⁺ regions, as defined by the fabrication process. Accordingly, hollow squares of p⁻ epi material 906 (grown on a p substrate 910) separate covered and uncovered n⁺ regions, as seen in FIG. 9A. While the layout geometry of photodetector 902 produces a deferred current (i_{D}) that requires less boosting, photodetector 902 does not have an optimal area efficiency. This can be appreciated best in both FIGS. 9A and 9B.

The inventors of the present invention have produced a layout geometry that results in good area efficiency, thereby increasing the immediate current (i_{I}), while also producing a deferred currents (i_{D}) that requires less boosting, resulting in a photodetector having excellent sensitivity and detectivity. Such a photodetector is shown in FIGS. 8A-8C. FIG. 8A illustrates a top view of a photodetector 802 according to an embodiment of the present invention. FIGS. 8B and 8C are cross-sectional views of photodetector 802. In these FIGS., uncovered n⁺ regions 804a are generally hexagon shaped regions that are electrically connected to one another (electrical connections are not shown), and covered n⁺ region 804b (covered by light blocking material 916) is shown as being shaded and surrounding uncovered n⁺ regions 804a. As can be seen, covered n⁺ region 804b has a generally honeycomb shape. An area efficiency of about 60% or greater can be achieved using the geometry layout of photodetector 802, thereby increasing immediate current (i_{I}), while also producing a deferred currents (i_{D}) that requires less boosting.

Embodiments of the present invention can be used in any application that implements a photodetector, which is also know as a light detector or a photodiode. For example, embodiments of the present invention can be used to produce an optical pickup in a CD-ROM or DVD-ROM drive. Embodiments of the present invention can also be used for fiber optic applications or optocoupler applications. These are just a few exemplary applications for embodiments of the present invention, and are not meant to be limiting.

In the above described embodiments, n-regions are described as being implanted in a p-region. For example, in the embodiment of FIGS. 5A and 5B, n⁺ regions 504a and 504b are implanted in p⁻ region 506. In alternative embodiments, the semiconductor conductivity materials are reversed. That is, p-regions are implanted in an n-region. Preferably, heavily doped p⁺ regions are implanted in a lightly doped n⁻ region. In such embodiments, the collective layout area of the uncovered p⁺ region(s) is greater that the collective layout area of the covered p⁺ regions(s), to improve sensitivity, detectivity and/or area efficiency.

The above described photodetectors of the present invention are shown as being CMOS photodetectors. However, while features of the present invention will produce the most significant improvements in CMOS photodetectors, the features of the present invention can be implemented in other technologies, such as (but not limited to) bipolar silicon technology and Gallium Arsenide technology. While such alternative technologies have already been used to produce fast detectors, the features of the present invention can be used to make even faster detectors.

The term photodetector is typically used to refer to a device that converts incident light to a current or voltage. Embodiments of the present invention are directed to such photodetectors. Embodiments of the present invention are also directed to the circuitry and/or other devices that are used to adjust the currents and/or voltages generated by photodetectors. In other words, embodiments of the present invention are directed to systems or apparatuses that include photodetectors and systems or apparatuses that are used with photodetectors. Throughout this specification and in the claims below, the term “photodetector” has often been used to also refer to such systems or apparatuses.

The forgoing description is of the preferred embodiments of the present invention. These embodiments have been provided for the purposes of illustration and description, but are not intended to be exhaustive or to limit the invention to the precise forms disclosed. Many modifications and variations will be apparent to a practitioner skilled in the art. Embodiments were chosen and described in order to best describe the principles of the invention and its practical application, thereby enabling others skilled in the art to understand the invention. It is intended that the scope of the invention be defined by the following claims and their equivalents.

What is claimed:

1. A photodetector, comprising:
a p-type region;
a first n-type region forming a first pn junction with said p-type region, said first n-type region having a first layout area;
a second n-type region, separated from said first n-type region, forming a second pn junction with said p-type region, said second n-type region having a second layout area that is greater than said first layout area;
a light blocking material covering said first n-type region; and
a current booster;
wherein carriers are produced in said p-type region when light is incident on said second n-type region, a portion of said carriers being quickly captured by said second n-type region, a remaining portion of said carriers being slow carriers that wander around in said p-type region prior to being captured, a first portion of said slow carriers eventually being captured by said first n-type region, and a second portion of said slow carriers eventually being captured by said second n-type region, said first pn junction generating a first current resulting from said first portion of said slow carriers, and said second pn junction generating a second current resulting from both said quickly captured portion of said carriers and said second portion of said slow carriers; and
wherein said current booster is adapted to boost said first current so that said first current is substantially equal to a portion of said second current that is due to said second portion of said slow carriers.

2. The photodetector of claim 1, further comprising a combiner adapted to subtract said first current from said second current to produce a difference signal having a fast response, said difference signal being an output of the photodetector.

3. The photodetector of claim 1, further comprising:
a first current-to-voltage converter that converts said first current to a first voltage;
a second current-to-voltage converter that converts said second current to a second voltage; and
a combiner to subtract said first voltage from said second voltage to produce a difference signal having a fast response, said difference signal being an output of the photodetector.

4. The photodetector of claim 1, wherein:
said first n-type region and said second n-type region are each n⁺ regions that are heavily doped; and
said p-type region is a p⁻ epi region that is lightly doped.

5. The photodetector of claim 1, wherein each of said first and second pn junctions are reverse biased.

6. A photodetector, comprising:
a p-type region;
a plurality of n-type regions each forming a separate pn junction with said p-type region, each of said pn junctions being reverse biased; a first portion of said n-type regions being covered, electrically connected to one another, and collectively having a covered layout area; a second portion of said n-type regions being uncovered, electrically connected to one another, and collectively having an uncovered layout area that is greater than said covered layout area; wherein when light is incident on said uncovered second portion of said n-type regions, a first current is produced based on carriers collected by said covered first portion of said n-type regions, and a second current is produces based on carriers collected by said uncovered second portion of said n-type regions; and
a means for boosting said first current to compensate for said uncovered layout area being greater than said covered layout area, prior to a current or voltage corresponding to said first current being subtracted from a current or voltage corresponding to said second current.

7. The photodetector of claim 6, further comprising a combiner adapted to subtract said first current from said second current to produce a difference signal having a fast response, said difference signal being an output of the photodetector.

8. The photodetector of claim 6, further comprising:
a first current-to-voltage converter that converts said first current to a first voltage;
a second current-to-voltage converter that converts said second current to a second voltage; and
a combiner to subtract said first voltage from said second voltage to produce a difference signal having a fast response, said difference signal being an output of the photodetector.

9. The photodetector of claim 6, wherein:
said n-type regions are each n⁺ regions that are heavily doped; and
said p-type region is a p⁻ epi region that is lightly doped.

10. The photodetector of claim 6, wherein said means for adjusting is adapted to adjust at least one of said first and second currents such that a portion of each of said currents due to said slow carriers is substantially equal.

11. The photodetector of claim 6, wherein:
said second portion of said n-type regions that are uncovered includes a plurality of separate generally hexagon shaped n-type regions that are electrically connected to one another; and
said covered first portion of said n-type regions generally surrounds said plurality of hexagon shaped n-type regions, forming a generally honey-comb shape.

12. A photodetector, comprising:
a p-type region;
a plurality of n-type regions each forming a separate pn junction with said p-type region;
a first portion of said n-type regions being covered and collectively having a covered layout area; and
a second portion of said n-type regions being uncovered and collectively having an uncovered layout area that is greater than said covered layout area,
wherein said uncovered second portion of said n-type regions includes a plurality of separate generally hexagon shaped n-type regions that are electrically connected to one another.

13. The photodetector of claim 12, wherein said covered first portion of said n-type regions generally surrounds said plurality of hexagon shaped n-type regions.

14. The photodetector of claim 13, wherein said covered first portion of said n-type regions has a generally honey-comb shape.

15. The photodetector of claim 12, wherein:
when each of said pn junctions are reverse biased and light is incident on said uncovered second portion of said n-type regions, a first current is produced based on carriers collected by said covered first portion of said n-type regions, and a second current is produces based on carriers collected by said uncovered second portion of said n-type regions;
the photodetector further comprising:
a means for adjusting at least one of said first and second currents to compensate for said uncovered layout area being greater than said covered layout area, prior to a current or voltage corresponding to said first current being subtracted from a current or voltage corresponding to said second current.

16. The photodetector of claim 12, wherein:
said n-type regions are each n⁺ regions that are heavily doped; and
said p-type region is a p⁻ epi region that is lightly doped.

17. The photodetector of claim 16, wherein said means for adjusting is adapted to adjust at least one of said first and second currents such that a portion of each of said currents due to slow carriers is substantially equal.

18. The photodetector of claim 12, wherein, when light is incident on said uncovered second portion of said n-type regions, a first current is produced based on carriers collected by said covered first portion of said n-type regions, and a second current is produces based on carriers collected by said uncovered second portion of said n-type regions, the photodetector further comprising:
a first current-to-voltage converter that converts said first current to a first voltage;
a second current-to-voltage converter that converts said second current to a second voltage; and
a means for adjusting at least one of said first and second voltages to compensate for said uncovered layout area being greater than said covered layout area, prior said first voltage being subtracted from said second voltage.

19. The photodetector of claim 18, wherein said means for adjusting is adapted to adjust at least one of said first and second voltages such that a portion of each of said voltages due to slow carriers is substantially equal.

20. A method for providing a photodetector having a fast response, comprising:
(a) providing a first conductivity type semiconductor material;
(b) providing a plurality of regions of a second conductivity type semiconductor material, each of said plurality of regions forming a pn junction with said first conductivity type material, a first portion of said regions being covered and collectively having a covered layout area, a second portion of said regions being uncovered and collectively having an uncovered layout area, said uncovered layout area being greater than said covered layout area;
(c) reverse biasing each pn junction;
(d) exposing said layout areas to incident light to thereby produce a first current based on carriers collected by said covered first portion of said regions, and a second current based on carriers collected by said uncovered portion of said regions;
(e) boosting said first current to compensate for said uncovered layout area being greater than said covered layout area; and
(f) subtracting a current or voltage corresponding to said first current from a current or voltage corresponding to said second current, to produce a current or voltage difference signal having a fast response.

21. The method of claim 20, wherein:
said first conductivity type semiconductor material comprises a p-type semiconductor material; and
said second conductivity type semiconductor material comprises an n-type semiconductor material.

22. The method of claim 20, wherein:
said first conductivity type semiconductor material comprises an n-type semiconductor material; and
said second conductivity type semiconductor material comprises a p-type semiconductor material.

23. The method of claim 20, wherein step (e) comprises adjusting at least one of said first and second currents so that said first current is substantially equal to a portion of said second current that is due to slow carriers.

24. A method for providing a photodetector having a fast response, comprising:
(a) providing a first conductivity type semiconductor material;
(b) providing a plurality of regions of a second conductivity type semiconductor material, each of said plurality of regions forming a pn junction with said first conductivity type material, a first portion of said regions being covered and collectively having a covered layout area, a second portion of said regions being uncovered and collectively having a uncovered layout area, said uncovered layout area being greater than said covered layout area;
(c) reverse biasing each pn junction;
(d) exposing said covered and uncovered layout areas to incident light to thereby produce a first current based on carriers collected by said covered first portion of said regions, and a second current based on carriers collected by said uncovered portion of said regions;
(e) converting said first current to a first voltage, and said second current to a second voltage;
(f) increasing the first voltage to compensate for said uncovered layout area being greater than said covered layout area; and
(g) subtracting said first voltage from said second voltage to produce a voltage difference signal having a fast response.

25. The method of claim 24, wherein:
said first conductivity type semiconductor material comprises a p-type semiconductor material; and
said second conductivity type semiconductor material comprises an n-type semiconductor material.

26. The method of claim 24, wherein:
said first conductivity type semiconductor material comprises an n-type semiconductor material; and
said second conductivity type semiconductor material comprises a p-type semiconductor material.

27. The method of claim 24, wherein step (e) comprises adjusting said first voltage so that said first voltage is substantially equal to a portion of said second voltage that is due to slow carriers.

28. A photodetector, comprising:
a first conductivity type lightly doped semiconductor material;
one or more heavily doped regions of semiconductor material of a second conductivity type, each forming a pn junction with said first conductivity type lightly doped semiconductor material, said one or more regions collectively having a first layout area and producing a first current;
one or more further heavily doped regions of semiconductor material of said second conductivity type each forming a pn junction with said first conductivity type lightly doped semiconductor material, said one or more further regions collectively having a second layout area and producing a second current, said first layout area being greater than said second layout area;
a light blocking material covering said one or more further regions; and
a means for boosting said first current to compensate for said first layout area being greater than said second layout area, prior to a current or voltage corresponding to said first current being subtracted from a current or voltage corresponding to said second current.

29. The photodetector of claim 28, wherein:
said first conductivity type semiconductor material is a p-type material; and
said second conductivity type semiconductor material is an n-type material.

30. The photodetector of claim 29, wherein:
said first conductivity type semiconductor material is an n-type material; and
said second conductivity type semiconductor material is an p-type material.

31. A photodetector, comprising:
a first conductivity type semiconductor material;
a plurality of generally hexagonal regions of semiconductor material of a second conductivity type, each forming a pn junction with said first conductivity type semiconductor material, said plurality of regions collectively having a first layout area;
one or more further regions of semiconductor material of said second conductivity type each forming a pn junction with said first conductivity type semiconductor material, said further regions collectively having a second layout area; and
a light blocking material covering said one or more further regions;
wherein each of said first layout area and said second layout area are generally symmetrical in both X and Y directions.

32. The photodetector of claim 31, wherein said one or more further regions has a generally honeycomb shape.

33. The photodetector of claim 31, wherein said one or more further regions comprise a single generally honeycomb shaped region that generally surrounds said generally hexagonal regions.
